(19) United States
(12) Patent Application Publication
(10) Pub. No.: US 2026/0011977 A1
(43) Pub. Date: Jan. 8, 2026

(54) IDENTICAL ACTIVE ELECTRO-ABSORPTION MODULATED LASER WITH LOSS-COUPLED PARTIAL GRATING DFB-LD

(71) Applicants: ELECTRONICS AND TELECOMMUNICATIONS RESEARCH INSTITUTE, Daejeon (KR); OPTO ELECTRONICS SOLUTIONS, Gwangju (KR)

(72) Inventors: Namje KIM, Daejeon (KR); O-kyun Kwon, Daejeon (KR); Joon Sang Yu, Yongin-si (KR); Ki-Hong Yoon, Gwangju (KR); Seungchul Lee, Daejeon (KR)

(73) Assignees: ELECTRONICS AND TELECOMMUNICATIONS RESEARCH INSTITUTE, Daejeon (KR); OPTO ELECTRONICS SOLUTIONS, Gwangju (KR)

(21) Appl. No.: 19/257,789

(22) Filed: Jul. 2, 2025

(30) Foreign Application Priority Data
Jul. 3, 2024 (KR) 10-2024-0087717

(51) Int. Cl. H01S 5/026; H01S 5/12

(52) U.S. Cl. CPC H01S 5/0265; H01S 5/12

(57) ABSTRACT

Provided is an electro-absorption modulated laser including a lower clad including an electro-absorption modulation (EAM) region and a laser diode (LD) region, an upper clad on the lower clad, an active layer between the lower clad and the upper clad, an upper electrode on the upper clad, and a grating in the upper clad, wherein the grating includes a first grating and a second grating on an upper surface of the first grating, a band gap wavelength of the first grating is less than a wavelength of laser light output from the LD region, and a bad gap wavelength of the second grating is larger than the wavelength of the laser light.

### CROSS-REFERENCE TO RELATED APPLICATIONS

This U.S. non-provisional patent application claims priority under 35 U.S.C. § 119 of Korean Patent Application No. 10-2024-0087717, filed on Jul. 3, 2024, the entire contents of which are hereby incorporated by reference.

### BACKGROUND

The present disclosure herein relates to an electro-absorption modulated laser used as a core optical device for 5G or 6G wireless communication, and more particularly, to an identical active electro-absorption modulated laser (IA-EML) with loss-coupled partial grating DFB-LD.

In 5G/6G wireless communication, 100 Gbps-class high-speed optical devices are essential for implementing a high-speed communication network. In particular, as a communication speed increases, an electro-absorption modulated laser (EML), which has excellent chirp characteristics and is thus advantageous for long-distance transmission, is used as a core optical device. An EML is a device in which a distributed feedback laser diode (DFB-LD) that oscillates in a single mode and a high-speed modulator using electro-absorption are integrated into a single chip. A DFB-LD requires a single-mode operation, characteristics insensitive to external reflection, high output, and the like. Therefore, a structure of a grating that determines characteristics of a DFB-LD is an important factor that determines not only the characteristics of a DFB-LD but also characteristics of an EML.

A representative example of a grating which is insensitive to external reflection characteristics and exhibits a high single-mode oscillation yield is a λ/4 phase-shifted grating structure. The λ/4 phase-shifted grating structure is a structure in which a phase-shifted region is inserted into a particular portion of a grating. Since periodicity of the grating is broken in the phase-shifted region, the grating is formed through e-beam lithography. However, the e-beam lithography requires expensive equipment and long processing time, and thus causes an increase in the price of laser devices.

On the contrary, a partial grating structure is a structure in which a uniform grating is formed only in a partial region in an output terminal direction within a DFB-LD. Since the partial grating structure uses a grating of a uniform interval, e-beam lithography equipment is not required.

A grating used in a DFB-LB may be classified by structural characteristics as described above, but may also be classified by characteristics of a material used in the grating. When the material of a grating is defined only by a difference of a material index in a Bragg wavelength that is an operating wavelength of the grating, the grating is classified as an index-coupled grating. On the contrary, when a grating has a structure having a periodic loss/gain together with the difference of a material index, the grating may be classified as a loss-coupled or gain-coupled grating. Such a grating is classified as a complex-coupled grating. A complex-coupled grating makes it possible to improve a single-mode yield by inducing a difference of a threshold gain by using absorption or gain of −1 mode and +1 mode that is a cause of the reduction of the yield of an index-coupled grating.

It is important to adopt an appropriate grating considering the structure, material, and the like of a grating as described above in order to secure characteristics of an IA-EML.

### SUMMARY

The present disclosure provides an electro-absorption modulated laser having an improved single-mode yield.

The problems to be solved by the inventive concept are not limited to the above-mentioned problems, and other problems not mentioned would be clearly understood by those of ordinary skill in the art from the disclosure below.

An embodiment of the inventive concept provides an electro-absorption modulated laser including: a lower clad including an electro-absorption modulation (EAM) region and a laser diode (LD) region; an upper clad on the lower clad; an active layer between the lower clad and the upper clad; an upper electrode on the upper clad; and a grating in the upper clad, wherein the grating includes a first grating and a second grating on an upper surface of the first grating, a band gap wavelength of the first grating is less than a wavelength of laser light output from the LD region, and a bad gap wavelength of the second grating is larger than the wavelength of the laser light.

In an embodiment of the inventive concept, an electro-absorption modulated laser includes: a lower clad including an electro-absorption modulation (EAM) region and a laser diode (LD) region; an upper clad on the lower clad; an active layer between the lower clad and the upper clad; an upper electrode on the upper clad; and a grating in the upper clad, wherein the grating includes a first grating and a second grating on an upper surface of the first grating, the first grating includes a first material having a band gap wavelength less than a wavelength of laser light output from the LD region, and the second grating includes a second material having a band gap wavelength larger than the wavelength of the laser light.

In an embodiment of the inventive concept, an electro-absorption modulated laser includes: a lower clad including an electro-absorption modulation (EAM) region and a laser diode (LD) region; an upper clad on the lower clad; an active layer between the lower clad and the upper clad; an upper electrode on the upper clad; and a grating provided in the upper clad and having a uniform interval on the LD region, wherein the grating includes a first grating and a second grating on an upper surface of the first grating, a band gap wavelength of the first grating is less than a wavelength of laser light output from the LD region, and a bad gap wavelength of the second grating is larger than the wavelength of the laser light.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view of an electro-absorption modulated laser according to a comparative example of the inventive concept;

FIGS. 2A and 2B are graphs showing a single-mode oscillation yield of an electro-absorption modulated laser using a partial grating structure according to the comparative example of the inventive concept;

FIG. 3 is a graph showing a yield, according to reflectivity of an anti-reflective film, of an electro-absorption modulated laser according to the comparative example of the inventive concept;

FIG. 4 is a graph showing two different oscillation spectra according to a phase between surfaces of a high reflective film and a grating;

FIG. 5 is a graph showing an oscillation spectrum according to a phase between surfaces of a high reflective film and a grating when reflectivity of an anti-reflective film is about 0.5% and a coupling coefficient is 58/cm;

FIG. 6 is a graph showing a distribution of power of an internal mode in case of in-phase and out-of-phase according to a change in a phase between surfaces of a high reflective film and a grating;

FIG. 7 is a cross-sectional view of an electro-absorption modulated laser according to some embodiments of the inventive concept;

FIG. 8 is an enlarged view of portion P1 of FIG. 7;

FIG. 9 is a graph showing an SMSR according to a phase between surfaces of a high reflective film and a grating and a ratio of an imaginary part to a real part of a coupling coefficient;

FIG. 10 is a graph showing oscillation spectra according to a phase between surfaces of a high reflective film and a grating and a ratio of an imaginary part to a real part of a coupling coefficient; and

FIG. 11 is a graph showing a single-mode yield according to a ratio of an imaginary part to a real part of a coupling coefficient.

### DETAILED DESCRIPTION

Embodiments of the inventive concept will now be described in detail with reference to the accompanying drawings. Advantages and features of embodiments of the inventive concept, and methods for achieving the advantages and features will be apparent from the embodiments described in detail below with reference to the accompanying drawings. However, the inventive concept may be embodied in different forms and should not be construed as limited to the embodiments set forth herein. Rather, these embodiments are provided so that this disclosure will be thorough and complete, and will fully convey the scope of the inventive concept to those skilled in the art, and the inventive concept is only defined by the scope of the claims. Like reference numerals refer to like elements throughout.

The terminology used herein is not for delimiting the embodiments of the inventive concept but for describing the embodiments. The terms of a singular form may include plural forms unless otherwise specified. It will be further understood that the terms “includes”, “including”, “comprises”, and/or “comprising”, when used ‘in this description, specify the presence of stated elements, operations, and/or components, but do not preclude the presence or addition of one or more other elements, operations, and/or components. Furthermore, reference numerals, which are presented in the order of description, are provided according to the embodiments and are thus not necessarily limited to the order.

The embodiments of the inventive concept will be described with reference to example cross-sectional views and/or plan views. In the drawings, the dimensions of layers and regions are exaggerated for clarity of illustration. Therefore, the forms of the example drawings may be changed due to a manufacturing technology and/or error tolerance. The embodiments of the inventive concept may involve changes of shapes depending on a manufacturing process, without being limited to the illustrated specific forms.

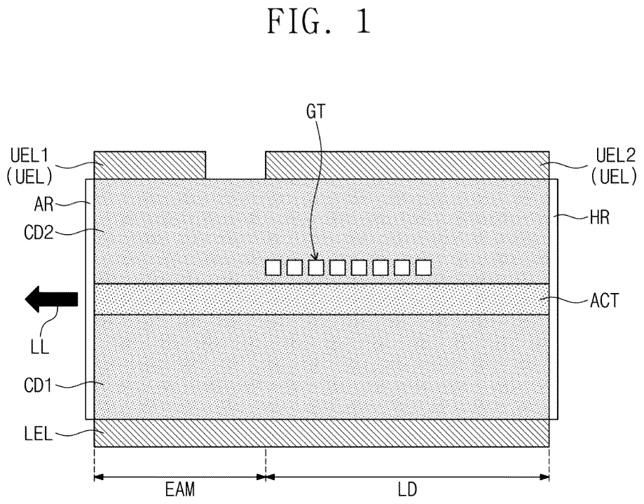

FIG. 1 is a cross-sectional view of an electro-absorption modulated laser according to a comparative example of the inventive concept.

Referring to FIG. 1, the electro-absorption modulated laser according to the comparative example of the inventive concept may include a lower clad CD1 including an electro-absorption modulation (EAM) region EAM and a laser diode (LD) region LD. The LD region LD may be a distributed feedback (DFB) region for generating laser light LL. The EAM region EAM may be a region for modulating the laser light LL.

An active layer ACT and an upper clad CD2 may be sequentially stacked on an upper surface of the lower clad CD1. For example, the active layer ACT may include at least one of InGaAsP, InGaAlAs, or InGaNAs. For example, the lower clad CD1 and the upper clad CD2 may each include p-InP or n-InP.

A grating GT may be provided in the upper clad CD2 on the LD region LD. The grating GT may vertically overlap the LD region LD. For example, the grating GT may not be provided in the upper clad CD2 on the EAM region EAM. For example, the grating GT may include a compound semiconductor. For example, the grating GT may include InGaAs or InGaAsP, but is not limited thereto. For example, a band gap wavelength of a material of the grating GT may be less than a wavelength of the laser light LL. Here, the grating GT may constitute an index grating. For another example, the band gap wavelength of the material of the grating GT may be larger than the wavelength of the laser light LL. Here, the grating GT may constitute a complex-coupled grating. The electro-absorption modulated laser according to the comparative example of the inventive concept may include the grating GT configured with a single layer, and the grating GT may be one of an index grating and a complex-coupled grating according to the material included in the grating GT.

The grating GT may be a grating having a uniform interval on the LD region LD. Accordingly, an electro-absorption modulated laser according to the inventive concept may adopt a partial grating structure.

An upper electrode UEL may be provided on an upper surface of the upper clad CD2. The upper electrode UEL may include a first upper electrode UEL1 provided on the upper surface of the upper clad CD2 on the EAM region EAM and a second upper electrode UEL2 provided on the upper surface of the upper clad CD2 on the LD region LD. For example, the first and second upper electrodes UEL1 and UEL2 may each include a conductive material such as metal.

A lower electrode LEL may be provided on a lower surface of the lower clad CD1. The lower electrode LEL may be provided under the EAM region EAM and the LD region LD. For example, a ground voltage may be applied to the lower electrode LEL.

A high reflective film HR may be provided on one sidewall of each of the lower clad CD1, the active layer ACT, and the upper clad CD2. The high reflective film HR may be disposed adjacent to the LD region LD. The high reflective film HR may reflect the laser light LL.

An anti-reflective film AR may be provided on another sidewall of each of the lower clad CD1, the active layer ACT, and the upper clad CD2. The anti-reflective film AR may be disposed adjacent to the EAM region EAM. The anti-reflective film AR may transmit the laser light LL from the active layer ACT to the outside without reflecting the laser light LL.

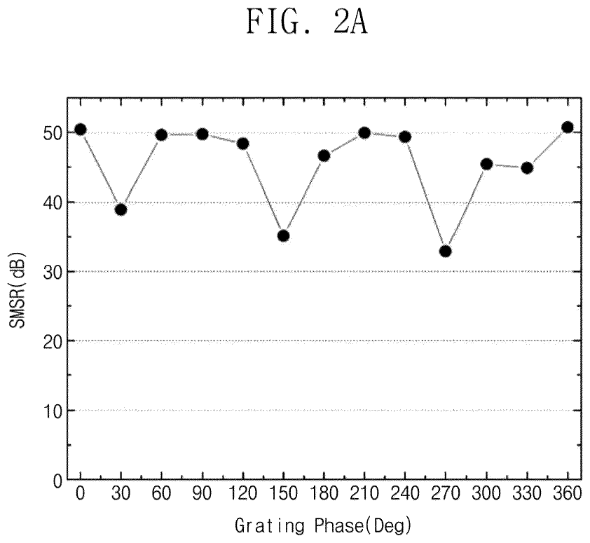

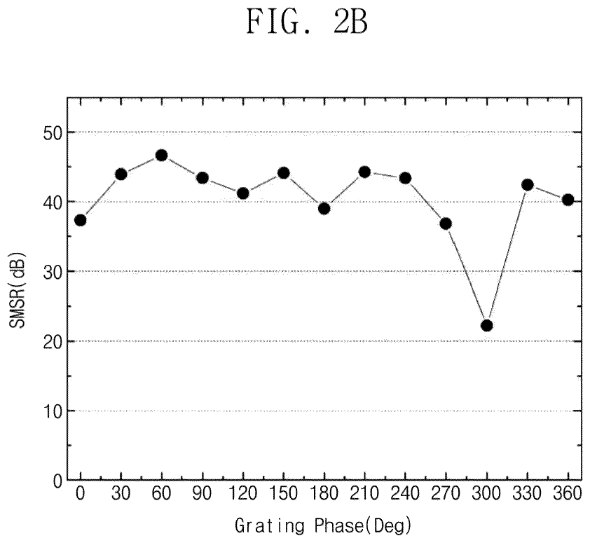

FIGS. 2A and 2B are graphs showing a single-mode oscillation yield of the electro-absorption modulated laser using a partial grating structure according to the comparative example of the inventive concept.

Referring to FIGS. 2A and 2B, FIG. 2A shows a result of estimating a single-mode oscillation yield of an IA-EML by calculating an SMSR according to a phase between surfaces of the high reflective film HR and the grating at a low coupling coefficient k. A normalized coupling coefficient kL of FIG. 2A is 1.5, and a normalized coupling coefficient kL of FIG. 2B is 3. FIGS. 2A and 2B show results of calculation obtained by changing a phase of the grating GT and the high reflective film HR, wherein a reference SMSR for single-mode calculation is set to 40 dB. Furthermore, the grating GT (FIG. 1) of the electro-absorption modulated laser according to the comparative example of the inventive concept is an index grating.

In general, a DFB-LD insensitive to external feedback is necessary for preventing noise and jitter. The coupling coefficient k may be increased to manufacture a DFB-LD insensitive to external feedback, and, accordingly, an intensity of light in the DFB-LD may increase. However, in the grating GT of FIG. 1, the single-mode oscillation yield may decrease when the coupling coefficient k is increased.

In detail, the single-mode oscillation yield is about 75% when the normalized coupling coefficient is 1.5. When the normalized coupling coefficient kL is 3, the single-mode oscillation yield decreases to about 67%, and a side mode suppression ratio (SMSR) of an oscillation mode decreases at the same time. For example, although not illustrated in the graphs, in general, the single-mode oscillation yield is calculated as about 70% when the normalized coupling coefficient kL suitable for IA-EML is 2.

In brief, the single-mode oscillation yield may decrease when the coupling coefficient k is increased to manufacture a DFB-LD insensitive to external feedback. Namely, the coupling coefficient k and the single-mode oscillation yield may have a trade-off relationship.

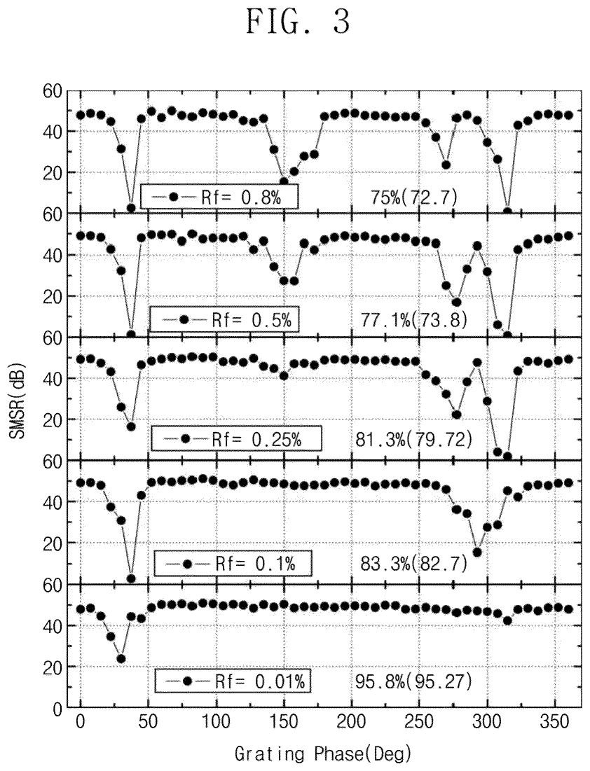

FIG. 3 is a graph showing a yield, according to reflectivity of the anti-reflective film AR, of the electro-absorption modulated laser according to the comparative example of the inventive concept.

Referring to FIG. 3, the single-mode oscillation yield is closely related to not only the normalized coupling coefficient kL but alto the reflectivity of the anti-reflective film AR. The single-mode is assumed to have at least about 40 dB of SMSR when calculating the single-mode oscillation yield. Furthermore, the grating GT (FIG. 1) of the electro-absorption modulated laser according to the comparative example of the inventive concept may be an index grating. When the coupling coefficient k is 58/cm, the single-mode oscillation yield is calculated to be reduced from about 95% to about 72.7% as the reflectivity of the anti-reflective film AR increases.

Therefore, considering FIGS. 2A, 2B, and 3 together, the single-mode oscillation yield of an IA-EML having the coupling coefficient k with excellent noise and jitter characteristics and the anti-reflective film AR with reflectivity of about 0.5% may reduce to about 70% or less. At the same time, it may be difficult for the IA-EML having the above characteristics to secure a high SMSR of 50 dB level.

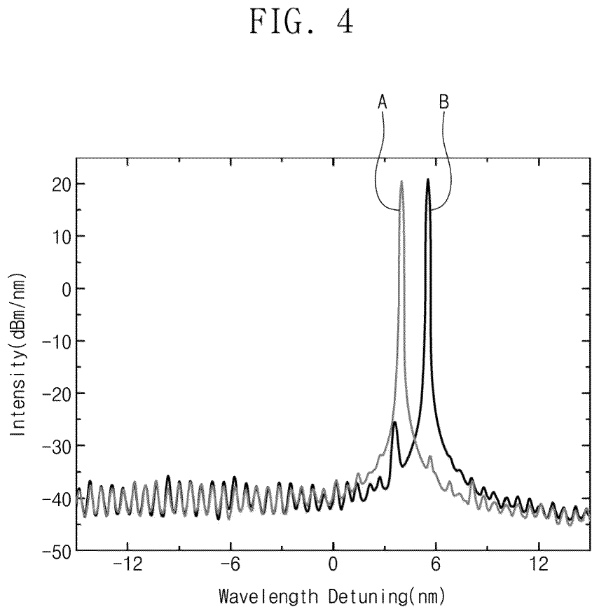

FIG. 4 is a graph showing two different oscillation spectra according to a phase between surfaces of the high reflective film HR and the grating. Hereinafter, a cause of the reduction in the yield of the electro-absorption modulated laser according to the comparative example of the inventive concept described above will be described with reference to FIG. 4.

Referring to FIG. 4, the grating GT (FIG. 1) of the electro-absorption modulated laser according to the comparative example of the inventive concept may be a partial grating and an index grating.

Referring to FIG. 4, it may be confirmed that two different oscillation modes (i.e., mode A and mode B) oscillate. It may be recognized that the mode A and mode B compete with each other according to a change in a phase between surfaces of the high reflective film HR and the grating. Since oscillation gains of the mode A and the mode B are similar, the mode A and the mode B may simultaneously oscillate. In addition, one of the mode A and the mode B is required to be stably oscillated at a particular grating phase, but the mode A and the mode B may randomly oscillate at the particular grating phase. As a result, the yield of the electro-absorption modulated laser according to the comparative example of the inventive concept may reduce.

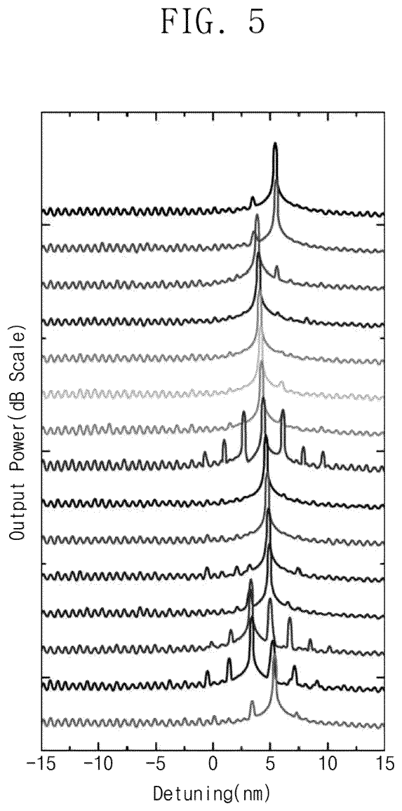

FIG. 5 is a graph showing an oscillation spectrum according to a phase between surfaces of the high reflective film HR and the grating when the reflectivity of the anti-reflective film AR is about 0.5% and the coupling coefficient k is 58/cm.

FIG. 5 is a graph showing an oscillation spectrum of an IA-EML calculated while changing a grating phase between surfaces of the high reflective film HR and the grating GT of the electro-absorption modulated laser according to the comparative example of the inventive concept described with reference to FIG. 1 from 0° to 350° in increments of 25°. As described above with reference to FIG. 4, two different oscillation modes may simultaneously oscillate and compete with each other. Furthermore, it may be confirmed that while one of the two different oscillation modes is oscillating, the oscillation spectrum has a form flowing in one direction according to the grating phase. In addition, since the two different oscillation modes oscillate, a four-wave mixing effect may occur, and, accordingly, multiple modes having equal intervals may be formed. As a result, the SMSR may sharply reduce, and the yield of the IA-EML may reduce.

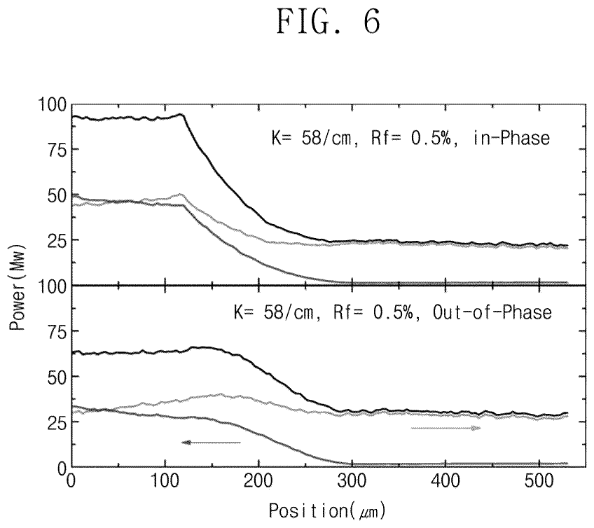

FIG. 6 is a graph showing a distribution of power of an internal mode in case of in-phase and out-of-phase according to a change in a phase between surfaces of the high reflective film HR and the grating.

FIG. 6 shows results of calculating the distribution of power of an IA-EML internal mode for each of the case where the DFB-LD of the LD region LD oscillates in a single mode since reflection between the LD region LD and the high reflective film HR is in-phase and the case where the DFB-LD of the LD region LD oscillates in multiple modes since the reflection between the LD region LD and the high reflective film HR is out-of-phase. Here, the calculation is performed on the assumption that the reflectivity of the anti-reflective film AR of the electro-absorption modulated laser according to the comparative example of the inventive concept is about 0.5% and the coupling coefficient k is 58/cm.

It may be confirmed that the power of the internal mode of the LD region LD is high and stable in an in-phase state. On the contrary, the power of the internal mode of the LD region LD is relatively low in an out-of-phase state. In this case, even when the LD region LD in the out-of-phase state oscillates in a single mode, the LD region LD may be sensitive to external reflection. As a result, jitter may significantly occur during high-speed modulation.

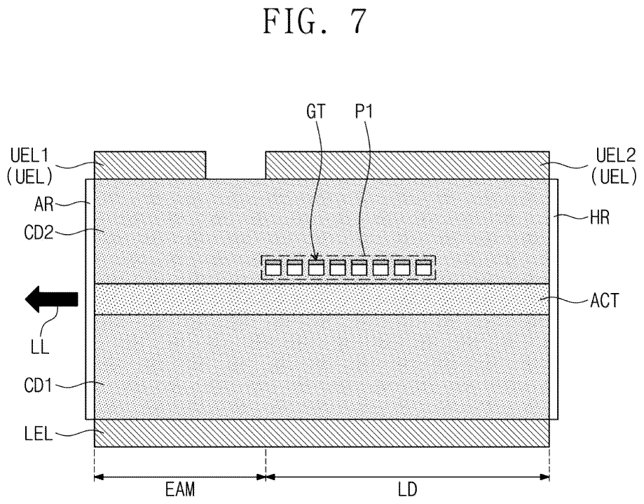

A configuration and characteristics (e.g., yield, SMSR, etc.) of the electro-absorption modulated laser according to the comparative example of the inventive concept have been described with reference to FIGS. 1 to 6. A configuration and characteristics of an electro-absorption modulated laser according to some embodiments of the inventive concept for overcoming limitations of the electro-absorption modulated laser according to the comparative example of the inventive concept will be described in detail with reference to FIGS. 7 to 11. For conciseness, descriptions overlapping with the above descriptions will not be provided.

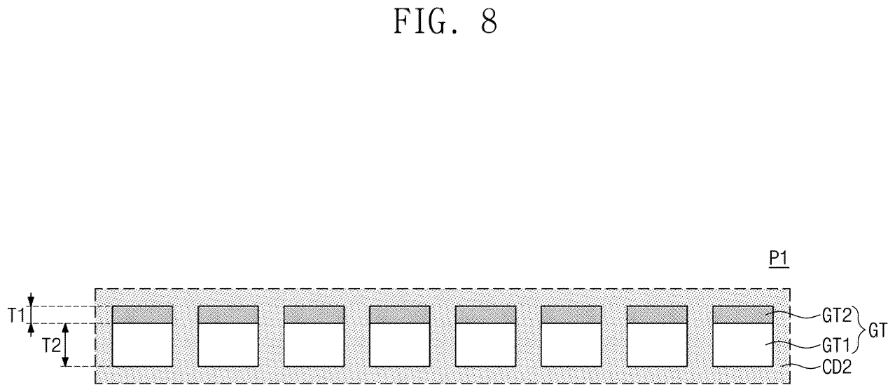

FIG. 7 is a cross-sectional view of an electro-absorption modulated laser according to some embodiments of the inventive concept. FIG. 8 is an enlarged view of portion P1 of FIG. 7.

The grating GT may include a first grating GT1 in the upper clad CD2 and a second grating GT2 on an upper surface of the first grating GT1. The first grating GT1 may include a material that does not absorb the laser light LL at a Bragg wavelength. The second grating GT2 may include a material that absorbs the laser light LL at the Bragg wavelength. Accordingly, the grating GT may constitute a complex-coupled grating.

A band gap wavelength of the first grating GT1 may be less than an operating wavelength of the LD region LD (i.e., wavelength of the laser light LL). Namely, a band gap wavelength of a first material included in the first grating GT1 may be less than the operating wavelength of the LD region LD. Here, the band gap wavelength of a certain material is defined as a value obtained by dividing a product of a Planck's constant h and a speed of light c by an energy band gap of the material. Accordingly, the material of the first grating GT1 may not have an absorption characteristic at the operating wavelength of the LD region LD. As a result, the first grating GT1 may constitute an index grating. The band gap wavelength of the first grating GT1 (i.e., the band gap wavelength of the first material) may be larger than the band gap wavelength of the upper clad CD2 (e.g., the band gap wavelength of the material included in the upper clad CD2).

On the contrary, the band gap wavelength of the second grating GT2 may be larger than the operating wavelength of the LD region LD (i.e., wavelength of the laser light LL). Namely, a band gap wavelength of a second material included in the second grating GT2 may be larger than the operating wavelength of the LD region LD. Accordingly, the material of the second grating GT2 may have an absorption characteristic at the operating wavelength of the LD region LD. As a result, the second grating GT2 may be configured as a loss-grating.

Since the grating GT constitutes a complex-coupled grating, the coupling coefficient k may have both a real part and an imaginary part. The real part of the coupling coefficient k may be determined by a difference of an index of the grating GT. The index of the grating GT may vary according to a material composition of the first grating GT1 and the second grating GT2 and a ratio between a thickness T1 of the first grating GT1 and a thickness T2 of the second grating GT2. The imaginary part of the coupling coefficient k may be determined according to an absorption characteristics of the grating GT. Since the grating GT includes the first grating GT1 not having an absorption characteristic and the second grating GT2 having an absorption characteristic, the real part and imaginary part of the coupling coefficient k may be independently adjusted.

In the case of a single-layer grating unlike the grating GT including the first and second gratings GT1 and GT2, the index may increase as an energy band gap of a material of the single-layer grating increases. As a result, an index and absorption coefficient of the single-layer grating is unable to be independently adjusted. Therefore, since the electro-absorption modulated laser according to some embodiments of the inventive concept adopts a structure of the grating GT having the first and second gratings GT1 and GT2, the above-mentioned limitations may be overcome.

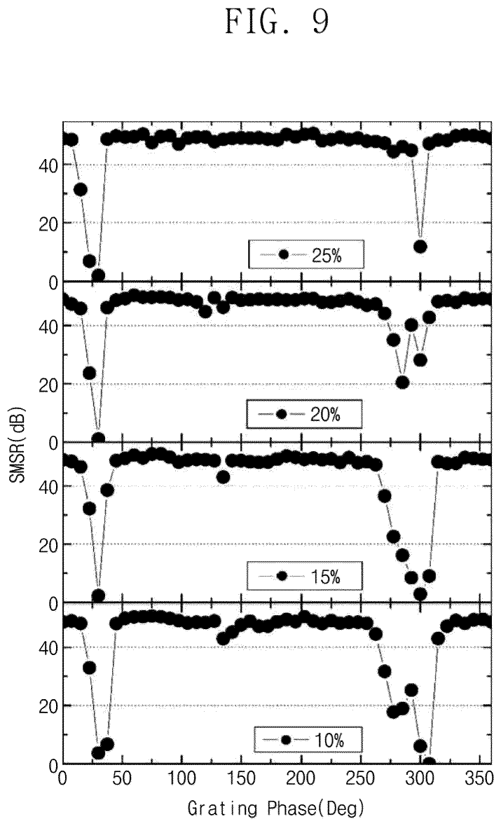

FIG. 9 is a graph showing an SMSR according to a phase between surfaces of the high reflective film HR and the grating and a ratio of the imaginary part to the real part of the coupling coefficient k.

FIG. 9 is a graph showing a result of calculating the SMSR while increasing the ratio of the imaginary part to the real part of the coupling coefficient k of the electro-absorption modulated laser according to some embodiments of the inventive concept. The operating wavelength of the LD region LD (FIG. 7) is set to 1.3 μm, the coupling coefficient k according to the real part of the grating GT (FIG. 7) is set to 58/cm, and the reflectivity of the anti-reflective film AR (FIG. 7) is set to 0.5%. The ratio of the imaginary part to the real part of the coupling coefficient k may vary according to a change of a material and thickness of each of the first grating GT1 (FIG. 8) and the second grating GT2 (FIG. 8).

Referring to FIG. 9, the SMSR and yield of the IA-EML may be improved as the ratio of the imaginary part to the real part of the coupling coefficient k increases.

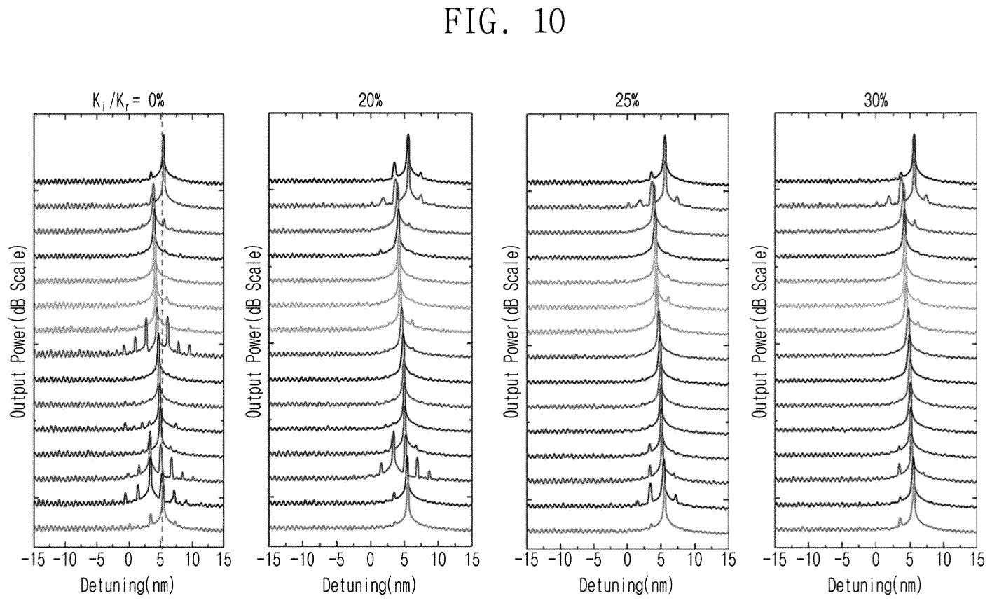

FIG. 10 is a graph showing oscillation spectra according to a phase between surfaces of the high reflective film HR and the grating and the ratio of the imaginary part to the real part of the coupling coefficient k.

The first graph of FIG. 10 relates to the electro-absorption modulated laser according to the comparative example of the inventive concept described with reference to FIG. 1. The other graphs of FIG. 10 relate to the electro-absorption modulated laser according to some embodiments of the inventive concept described with reference to FIG. 7.

Referring to FIG. 10, multi-mode oscillation may be suppressed as the ratio of the imaginary part to the real part of the coupling coefficient k increases. Grating phase regions oscillating in multiple modes may reduce as the ratio of the imaginary part to the real part of the coupling coefficient k increases. Since the electro-absorption modulated laser oscillates in a single mode at a particular grating phase, the yield of the electro-absorption modulated laser may be improved.

Such a change of characteristics is not caused by changing the situation of being out-of-phase described with reference to FIG. 6 to a situation of being in-phase. Since the first grating GT1 and the second grating GT2 described with reference to FIG. 8 are provided, an additional gain loss may occur in one mode during the competition between the multiple modes (i.e., the mode A and the mode B) described with reference to FIG. 4. Accordingly, a difference of a threshold gain between the multiple modes may increase. As a result, an additional gain is necessary for oscillating one mode in which an additional gain loss has occurred among the multiple modes. Therefore, since one of the multiple modes is suppressed, simultaneous oscillation of the multiple modes may reduce, and the yield of the electro-absorption modulated laser may be improved.

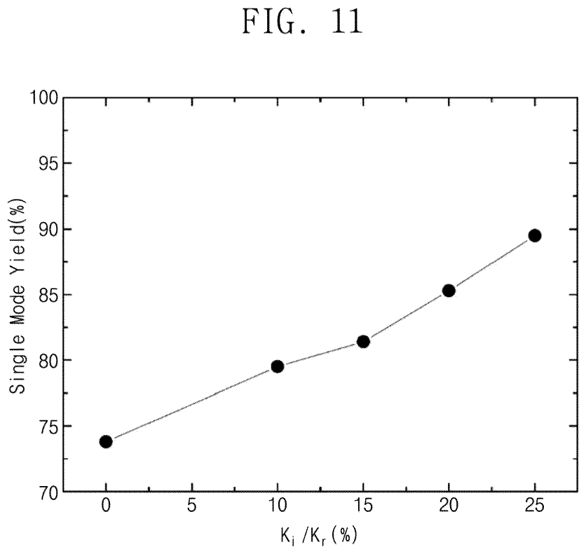

FIG. 11 is a graph showing a single-mode yield according to the ratio of the imaginary part to the real part of the coupling coefficient k.

Referring to FIG. 11, the yield of the IA-EML may be improved as the ratio of the imaginary part to the real part of the coupling coefficient k increases. However, when the ratio of the imaginary part to the real part of the coupling coefficient k excessively increases, an issue of self-pulsation or the like of the IA-EML may occur. As a result, characteristics of the IA-EML may deteriorate. Therefore, although a single-mode oscillation yield may increase as the ratio of the imaginary part to the real part of the coupling coefficient k increases, it may be difficult to adopt a grating having a large absorption characteristic.

Therefore, in the electro-absorption modulated laser according to some embodiments of the inventive concept, the ratio of the imaginary part to the real part of the coupling coefficient k may be about 0.1 to about 0.2. Referring to FIG. 11, the single-mode oscillation yield is calculated as about 80% to about 90% when the ratio of the imaginary part to the real part of the coupling coefficient k is about 0.1 to about 0.2.

According to the inventive concept, a partial grating structure, which is manufactured through a relatively simple manufacturing process, may be employed in the IA-EML. In addition, the grating may be configured as a multi-layer grating including a material having an absorption characteristic for the laser light LL (FIG. 7) and a material not having an absorption characteristic. Accordingly, the real part and the imaginary part of the coupling coefficient k may be independently adjusted, and additional gain loss may occur in one of two different multiple modes that compete with each other. As a result, a difference of a threshold gain between the multiple modes increases, and thus one of the multiple modes may be suppressed. Therefore, the yield of the electro-absorption modulated laser may be improved.

According to the inventive concept, a grating may include a first grating having a band gap wavelength less than a wavelength of laser light output from the LD region and a second grating provided on an upper surface of the first grating and having a band gap wavelength larger than the wavelength of the laser light output from the LD region. Accordingly, the grating may have a complex-coupled grating structure, and the real part and the imaginary part of the coupling coefficient may be independently adjusted by adjusting a material and thickness of each of the first grating and the second grating. As a result, when driving the electro-absorption modulated laser, a difference of a threshold gain between two different oscillation modes that may occur is increased, thus suppressing one of the two different oscillation modes. Therefore, the performance and yield of the electro-absorption modulated laser may be improved.

The above descriptions of embodiments of the inventive concept provide examples for describing the inventive concept. Therefore, the inventive concept is not limited to the above embodiments, and it would be obvious that those skilled in the art could make various modifications and changes by combining the above embodiments within the technical spirit of the inventive concept.

What is claimed is:

1. An electro-absorption modulated laser comprising:
a lower clad including an electro-absorption modulation (EAM) region and a laser diode (LD) region;
an upper clad on the lower clad;
an active layer between the lower clad and the upper clad;
an upper electrode on the upper clad; and
a grating in the upper clad,
wherein the grating includes a first grating and a second grating on an upper surface of the first grating,
a band gap wavelength of the first grating is less than a wavelength of laser light output from the LD region, and
a bad gap wavelength of the second grating is larger than the wavelength of the laser light.

2. The electro-absorption modulated laser of claim 1, wherein the first grating and the second grating include different materials.

3. The electro-absorption modulated laser of claim 1, wherein a height of the first grating is larger than a height of the second grating.

4. The electro-absorption modulated laser of claim 3, wherein a ratio of an imaginary part of a coupling coefficient to a real part of the coupling coefficient is adjusted according to a ratio between the height of the first grating and the height of the second grating.

5. The electro-absorption modulated laser of claim 1, wherein a ratio of an imaginary part of a coupling coefficient to a real part of the coupling coefficient is 0.1 to about 0.2.

6. The electro-absorption modulated laser of claim 1, wherein the grating vertically overlaps the LD region.

7. The electro-absorption modulated laser of claim 6, wherein the grating has a uniform interval.

8. The electro-absorption modulated laser of claim 1, wherein the band gap wavelength of the first grating is larger than a band gap wavelength of the upper clad.

9. The electro-absorption modulated laser of claim 1, wherein the first grating and the second grating each include a compound semiconductor.

10. An electro-absorption modulated laser comprising:
a lower clad including an electro-absorption modulation (EAM) region and a laser diode (LD) region;
an upper clad on the lower clad;
an active layer between the lower clad and the upper clad;
an upper electrode on the upper clad; and
a grating in the upper clad,
wherein the grating includes a first grating and a second grating on an upper surface of the first grating,
the first grating includes a first material having a band gap wavelength less than a wavelength of laser light output from the LD region, and
the second grating includes a second material having a band gap wavelength larger than the wavelength of the laser light.

11. The electro-absorption modulated laser of claim 10, wherein the band gap wavelength of the first material is larger than a band gap wavelength of a material included in the upper clad.

12. The electro-absorption modulated laser of claim 10, wherein a ratio of an imaginary part of a coupling coefficient to a real part of the coupling coefficient is 0.1 to about 0.2.

13. The electro-absorption modulated laser of claim 10, wherein the grating vertically overlaps the LD region.

14. The electro-absorption modulated laser of claim 13, wherein the grating has a uniform interval.

15. The electro-absorption modulated laser of claim 10, wherein the first grating and the second grating include different materials.

16. The electro-absorption modulated laser of claim 10, wherein a height of the first grating is larger than a height of the second grating.

17. An electro-absorption modulated laser comprising:
a lower clad including an electro-absorption modulation (EAM) region and a laser diode (LD) region;
an upper clad on the lower clad;
an active layer between the lower clad and the upper clad;
an upper electrode on the upper clad; and
a grating provided in the upper clad and having a uniform interval on the LD region,
wherein the grating includes a first grating and a second grating on an upper surface of the first grating,
a band gap wavelength of the first grating is less than a wavelength of laser light output from the LD region, and
a bad gap wavelength of the second grating is larger than the wavelength of the laser light.

18. The electro-absorption modulated laser of claim 17, wherein the first grating and the second grating include different materials.

19. The electro-absorption modulated laser of claim 17, wherein a ratio of an imaginary part of a coupling coefficient to a real part of the coupling coefficient is adjusted according to a ratio between the height of the first grating and the height of the second grating.

20. The electro-absorption modulated laser of claim 17, wherein a ratio of an imaginary part of a coupling coefficient to a real part of the coupling coefficient is 0.1 to about 0.2.
